(19) United States
(12) Patent Application Publication
(10) Pub. No.: US 2023/0198220 A1
(43) Pub. Date: Jun. 22, 2023

(54) OPTICAL FIBER SUPPORT STRUCTURE AND SEMICONDUCTOR LASER MODULE

(71) Applicant: FURUKAWA ELECTRIC CO., LTD., Tokyo (JP)

(72) Inventors: Masaya NAKAZUMI, Tokyo (JP); Satoshi SHIBUYA, Tokyo (JP); Naoki HAYAMIZU, Tokyo (JP); Ayato OKADA, Tokyo (JP)

(73) Assignee: FURUKAWA ELECTRIC CO., LTD., Tokyo (JP)

(21) Appl. No.: 18/166,691

(22) Filed: Feb. 9, 2023

Related U.S. Application Data
(63) Continuation of application No. PCT/JP2021/030444, filed on Aug. 19, 2021.

(30) Foreign Application Priority Data
Aug. 20, 2020 (JP) 2020-139502

(51) Int. Cl. H01S 5/02253; H01S 5/02326; H01S 5/06

(52) U.S. Cl. CPC H01S 5/02253; H01S 5/0607; H01S 5/02326

(57) ABSTRACT

An optical fiber support structure includes: a first portion configured to support an optical fiber including a core wire and a covering surrounding the core wire, the core wire including a core and a cladding; a second portion attached to the first portion; and a relaxing portion that is connected to an end portion of the core wire and that is positioned between the first portion and the second portion, the relaxing portion having a light receiving surface configured to receive light input from a space, an area of the light receiving surface being larger than an area of the end portion of the core wire.

### REFERENCE TO RELATED APPLICATIONS

This application is a continuation of International Application No. PCT/JP2021/030444, filed on Aug. 19, 2021 which claims the benefit of priority of the prior Japanese Patent Application No. 2020-139502, filed on Aug. 20, 2020, the entire contents of which are incorporated herein by reference.

### BACKGROUND OF THE INVENTION

The present disclosure relates to an optical fiber support structure and a semiconductor laser module.

In a semiconductor laser module that couples a spatially multiplexed laser beam to an end portion (input end) of a core wire of an optical fiber, there is conventionally known an optical fiber support structure in which a relaxing portion is provided so as to be in contact with the end portion. (e.g., WO 2017/134911 A)

### SUMMARY OF THE INVENTION

In this type of optical fiber support structure and a semiconductor laser module including the optical fiber support structure, there is a demand for an optical fiber support structure and a semiconductor laser module having an improved and novel configuration with fewer inconveniences in which, for example, a relaxing portion is less likely to come off, or a relaxing portion is easily attached during assembling the optical fiber support structure.

It is therefore desirable to obtain, for example, an optical fiber support structure and a semiconductor laser module including the optical fiber support structure having an improved and novel configuration with fewer inconveniences.

In some embodiments, an optical fiber support structure includes: a first portion configured to support an optical fiber including a core wire and a covering surrounding the core wire, the core wire including a core and a cladding; a second portion attached to the first portion; and a relaxing portion that is connected to an end portion of the core wire and that is positioned between the first portion and the second portion, the relaxing portion having a light receiving surface configured to receive light input from a space, an area of the light receiving surface being larger than an area of the end portion of the core wire.

In some embodiments, a semiconductor laser module includes: the optical fiber support structure; a semiconductor laser element; and an optical system configured to guide a laser beam output from the semiconductor laser element to the relaxing portion and couple the laser beam to the end portion of the core wire via the relaxing portion.

The above and other objects, features, advantages and technical and industrial significance of this disclosure will be better understood by reading the following detailed description of presently preferred embodiments of the disclosure, when considered in connection with the accompanying drawings.

### BRIEF DESCRIPTION OF THE DRAWINGS

FIG. 1 is an exemplary and schematic perspective view of a support of a first embodiment;

FIG. 2 is an exemplary and schematic plan view of the support of the first embodiment;

FIG. 3 is an explanatory diagram illustrating an optical path in an end cap of the first embodiment;

FIG. 4 is an exemplary and schematic front view of the support of the first embodiment;

FIG. 5 is a cross-sectional view taken along line V-V in FIG. 1;

FIG. 6 is an exemplary and schematic plan view of a support of a first modification of the first embodiment;

FIG. 7 is an exemplary and schematic front view of a support of a second modification of the first embodiment;

FIG. 8 is an exemplary and schematic front view of a support of a third modification of the first embodiment;

FIG. 9 is an exemplary and schematic front view of a support of a fourth modification of the first embodiment;

FIG. 10 is an exemplary and schematic front view of a support of a fifth modification of the first embodiment;

FIG. 11 is an exemplary and schematic front view of a support of a sixth modification of the first embodiment;

FIG. 12 is a cross-sectional view taken along line XII-XII in FIG. 11;

FIG. 13 is a cross-sectional view of a support of a seventh modification of the first embodiment at the same position as FIG. 12;

FIG. 14 is an exemplary and schematic front view of a support of an eighth modification of the first embodiment;

FIG. 15 is an exemplary schematic configuration diagram of a light emitting device of a second embodiment;

FIG. 16 is an exemplary and schematic perspective view of a portion of the light emitting device of the second embodiment; and

FIG. 17 is an exemplary schematic configuration diagram of a light emitting device of a third embodiment.

### DETAILED DESCRIPTION

In the following, exemplary embodiments and modifications are disclosed. The configurations of the embodiments and modifications described below and the actions and results (effects) brought about by the configurations are merely examples. The disclosure can also be realized by configurations other than those disclosed in the following embodiments and modifications. According to the disclosure, it is possible to obtain at least one of various effects (including derivative effects) obtained by the configurations.

The embodiments and modifications described below have similar configurations. Therefore, according to the configuration of each embodiment and modification, similar action and effect based on the similar configuration can be obtained. In the following, the similar configurations are denoted by the same reference numerals, and redundant description may be omitted.

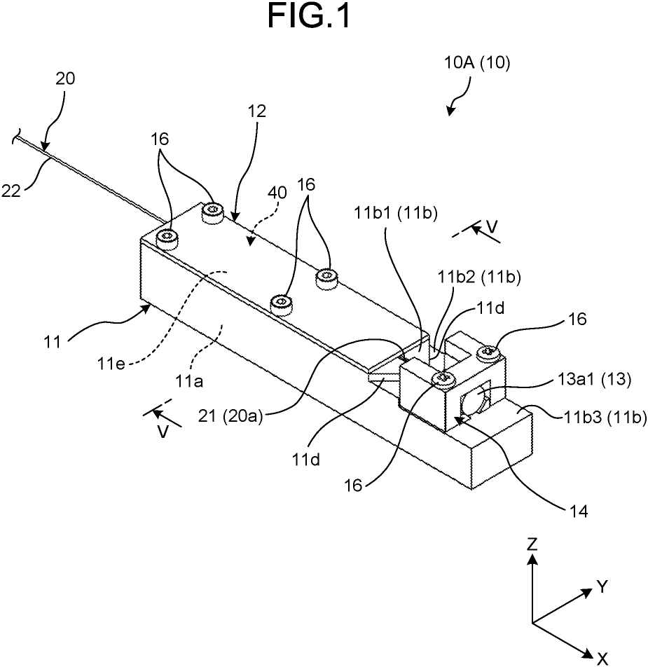

In each of FIGS. 1 to 5, the X direction is represented by an arrow X, the Y direction is represented by an arrow Y, and the Z direction is represented by an arrow Z. The X direction, the Y direction, and the Z direction intersect and are orthogonal to each other.

In the present description, ordinal numbers are given for convenience in order to distinguish parts, materials, portions, and others, and do not indicate priority or order.

### First Embodiment

FIG. 1 is a perspective view of a support 10A (10) of a first embodiment. The support 10A is mainly applied to support an end portion of an optical fiber 20 as an output optical fiber to output a laser beam in various optical instruments. The support 10A can also be referred to as an end portion support structure or a support portion. The support 10A is an example of an optical fiber support structure.

As illustrated in FIG. 1, the support 10A includes a base 11, a cover 12, an end cap 13, and a holder 14.

The base 11 has a rectangular parallelepiped shape extending in the X direction, and supports the optical fiber 20 extending in the X direction.

The base 11 has a surface 11a positioned at an end portion on the side opposite in the Z direction and a surface 11b positioned at an end portion in the Z direction.

The surface 11a faces a direction opposite to the Z direction, and intersects and is orthogonal to the Z direction. The surface 11a is a rectangular plane.

The surface 11b faces the Z direction, and intersects and is orthogonal to the Z direction. The surface 11b has three surfaces 11b1, 11b2, and 11b3 that are shifted in the Z direction. The surfaces 11b1, 11b2, and 11b3 all face the Z direction, and intersect and are orthogonal to the Z direction. The surfaces 11b1, 11b2, and 11b3 are all planes. The surface 11b2 is positioned to be shifted from the surface 11b1 in the direction opposite to the Z direction, and the surface 11b3 is positioned to be shifted from the surface 11b2 in the direction opposite to the Z direction. The surfaces 11b1, 11b2, and 11b3 form a step. The surface 11a, the surface 11b1, the surface 11b2, and the surface 11b3 are parallel to each other.

The cover 12 intersects and is orthogonal to the Z direction. The cover 12 has a rectangular shape extending in the X direction.

Both the base 11 and the cover 12 can be made of a material having high thermal conductivity, such as a copper-based material or an aluminum-based material.

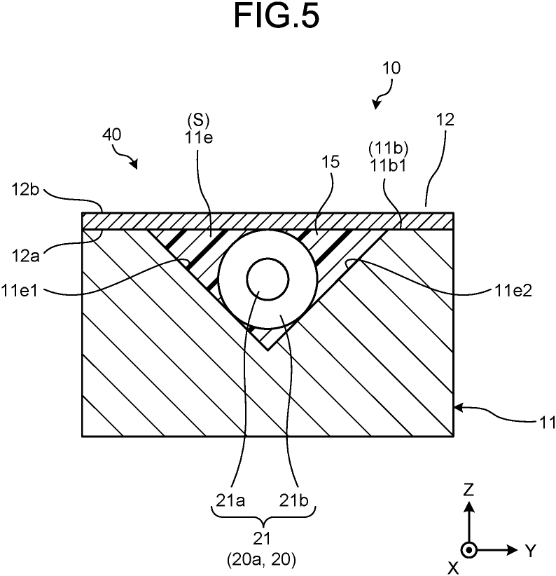

The optical fiber 20 is housed in a housing chamber S (see FIG. 5) which is provided between the base 11 and the cover 12 and extends in the X direction. The housing chamber S has an optical processing mechanism 40 formed therein. The optical processing mechanism 40 will be described later in the present description.

The cover 12 is fixed to the base 11 by, for example, a fixture 16 such as a screw. The base 11 and the cover 12 are integrated with each other in a state in which a stripped end portion 20a of the optical fiber 20 and a treatment material are housed in the space, whereby a configuration in which the stripped end portion 20a and the treatment material are housed in the space can be realized with a relatively simple configuration. The optical fiber 20 is supported by the base 11 and the cover 12. The base 11 and the cover 12 are examples of a first portion and can also be referred to as a support. Note that the base 11 and the cover 12 may be integrated with each other by a coupling method different from the coupling method using the fixture 16.

The end cap 13 is surrounded by the base 11 and the holder 14 positioned on the side opposite to the base 11 with respect to the end cap 13. The holder 14 is fixed to the base 11 by the fixture 16 such as a screw. The holder 14 is attached to the base 11 in a state in which the end cap 13 is sandwiched between the holder and the base 11. The holder 14 is an example of a second portion. Note that the base 11 and the holder 14 may be integrated with each other by a coupling method different from the coupling method using the fixture 16.

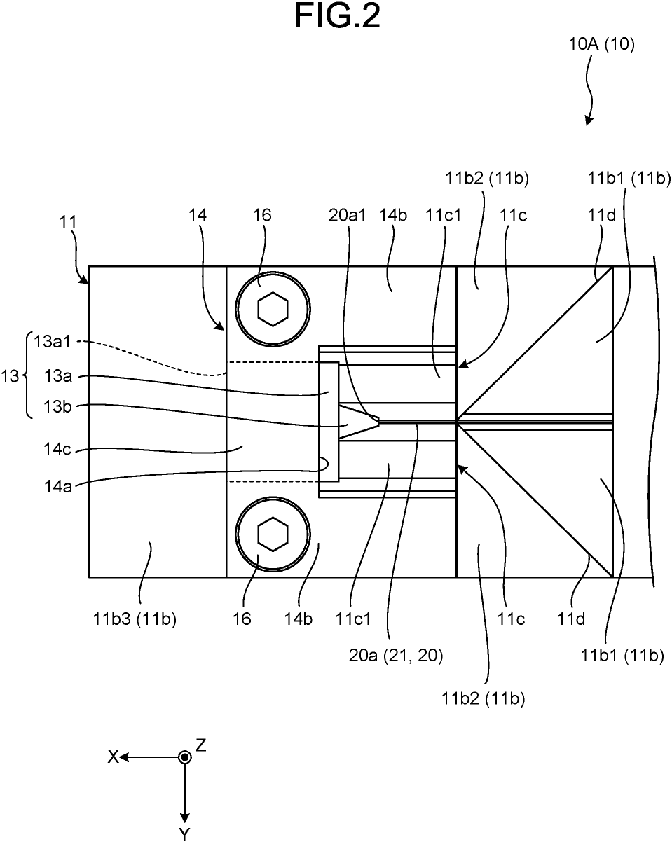

FIG. 2 is a partial plan view of the support 10A. As illustrated in FIG. 2, the end cap 13 faces a tip 20a1 of the stripped end portion 20a, that is, a tip 20a1 of a core wire 21 in the X direction. The end cap 13 has a columnar portion 13a and a protruding portion 13b. The columnar portion 13a has a columnar shape, has a diameter sufficiently larger than the diameter of the stripped end portion 20a, and extends in the X direction. An end surface 13a1 of the columnar portion 13a in the X direction has an area wider than the cross-sectional area of the tip 20a1. The protruding portion 13b has a conical and tapered shape, and protrudes in the direction opposite to the X direction so as to approach the tip 20a1 from the columnar portion 13a. The tip of the protruding portion 13b is, for example, fusion-bonded to the stripped end portion 20a. The tip 20a1 is an example of an end portion. Note that the shape of the end cap 13 is not limited to such a shape. For example, the end cap 13 may have only the columnar portion 13a without having the protruding portion 13b.

The end cap 13 is, for example, a transparent material having a transmittance of 99% or more with respect to light which is received by the end surface 13a1 and is transmitted through the optical fiber 20 (core wire 21). The end cap 13 can be made of a material having a refractive index substantially equal to that of the core of the optical fiber 20. As an example, the end cap 13 can be made of the same silica-based glass material as the core of the optical fiber 20.

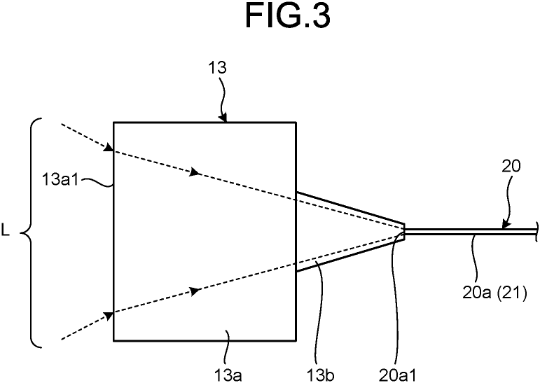

FIG. 3 is a schematic diagram illustrating an optical path of a laser beam L up to the tip 20a1 of the core wire 21 in the end cap 13. In a configuration in which the end cap 13 is not provided, if a laser beam condensed by a condenser lens (not illustrated) or others reaches the tip 20a1 of the stripped end portion 20a, the power density becomes excessively large as the beam diameter becomes smaller at the tip 20a1 serving as an interface, whereby an excessive temperature rise occurs, and thus the tip 20a1 may be damaged. Therefore, in the present embodiment, the end cap 13 is connected to the tip 20a1 to enlarge the interface. As illustrated in FIG. 3, in the present embodiment, since the laser beam L reaches the end surface 13a1 of the end cap 13, which is wider than the tip 20a1, in a state in which the beam diameter is larger and the power density is smaller, it is possible to suppress an excessive temperature rise and thus damage in both the end surface 13a1 serving as the interface and the tip 20a1 of the core wire 21 in the middle of a light guide. The end cap 13 is an example of a relaxing portion. The end surface 13a1 is an example of a light receiving surface.

An anti-reflection (AR) coating is applied to the end surface 13a1 of the end cap 13 on the side opposite to the protruding portion 13b. Thus, the reflection of light at the end surface 13a1 is suppressed.

As illustrated in FIG. 2, the holder 14 is provided with a cutout 14a which is opened in the direction opposite to the X direction. The cutout 14a allows a connecting portion between the protruding portion 13b of the end cap 13 and the tip 20a1 of the core wire 21 to be exposed in the Z direction, that is, on the side opposite to the base 11. Such a configuration allows to check a connection state between the protruding portion 13b and the tip 20a1 through the cutout 14a by visual confirmation of an operator or photographing by a camera, for example. The cutout 14a is an example of an opening.

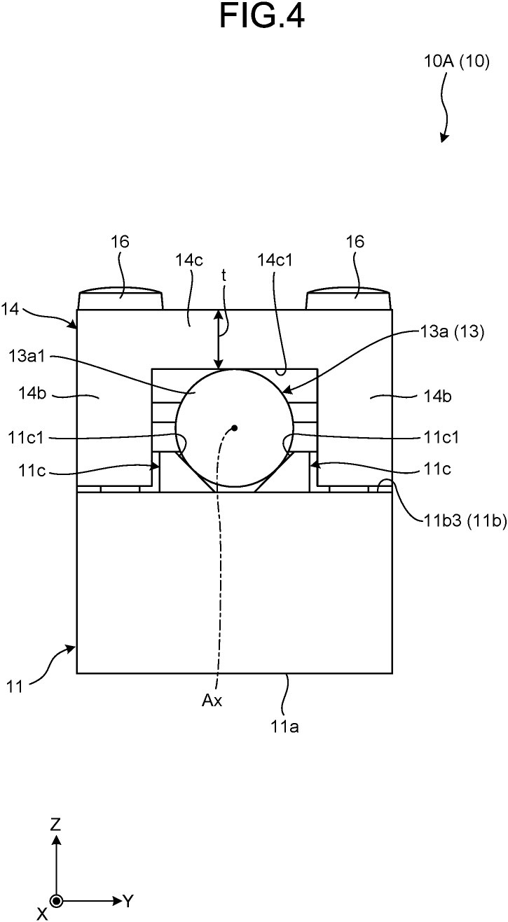

FIG. 4 is a front view of the support 10A when viewed in the direction opposite to the X direction. As illustrated in FIG. 4, the holder 14 is adjacent to the surface 11b3 of the base 11 in the Z direction.

The holder 14 has two side walls 14b spaced apart from each other in the Y direction and extending in the Z direction, and a top wall 14c extending in the Y direction between end portions of the side walls 14b in the Z direction. These two side walls 14b and the top wall 14c cover the columnar portion 13a of the end cap 13.

Two protrusions 11c are provided on the surface 11b3 of the base 11. The protrusions 11c each are spaced apart from each other in the Y direction, protrude from the surface 11b3 in the Z direction, and extend in the X direction. The protrusions 11c each have inclined surfaces 11c1. The inclined surfaces 11c1 face inward in the radial direction of the central axis (i.e., an optical axis Ax) of the columnar portion 13a of the end cap 13. The inclined surfaces 11c1 are planes extending in the direction (tangential direction) orthogonal to the radial direction of the optical axis Ax and extending in the axial direction of the optical axis Ax, that is, in the Z direction. The outer peripheral surface of the columnar portion 13a is in contact with these inclined surfaces 11c1.

The outer peripheral surface of the columnar portion 13a is also in contact with an inner surface 14c1 of the top wall 14c of the holder 14 on the side opposite to the two protrusions 11c. The inner surface 14c1 is a plane extending in the Y direction and extending in the Z direction. In other words, the inner surface 14c1 is also a plane extending in the direction (tangential direction) orthogonal to the radial direction of the optical axis Ax and extending in the axial direction of the optical axis Ax.

As described above, the outer peripheral surface of the columnar portion 13a is inscribed in the two inclined surfaces 11c1 and the inner surface 14c1, that is, three surfaces. The columnar portion 13a, that is, the end cap 13 is supported by the support 10A by line contact with these three surfaces or surface contact with an elongated surface extending in the X direction with a very small width. In this case, the support 10A can support the end cap 13 without using an adhesive or others.

In such a configuration, the holder 14 may be made of, for example, an invar material. In the present description, the invar material is a material that shrinks more than a normal temperature at a temperature higher than the normal temperature, and is, as an example, an iron-based alloy containing nickel (nickel alloy). For example, in a case where this type of the support 10A is incorporated in a device including an adhesive as a thermosetting resin, the support 10A may be in a high temperature state after sub-assembly (after assembly). The temperature in the high-temperature state in the thermosetting treatment is, for example, 130 [°C.]. In such a case, if the configuration is such that the thermal expansion of the end cap 13 is hindered by the base 11 and the holder 14, the stress acting on the end cap 13 or the stripped end portion 20a connected to the end cap 13 increases, which may cause deformation or damage of the end cap 13 or the stripped end portion 20a. In this regard, in the case where the holder 14 is made of an invar material, even when the end cap 13 is thermally expanded, the thicknesses t of the top wall 14c of the holder 14 is reduced and the thermal expansion of the end cap 13 is not excessively hindered, so that deformation or damage of the end cap 13 or the stripped end portion 20a can be suppressed.

As illustrated in FIGS. 1 and 2, a reflecting portion 11d is provided at a position away from the end cap 13 on the side opposite in the X direction. The reflecting portion 11d faces the end cap 13. The reflecting portion 11d is provided on a stepped surface extending in the Z direction between the surface 11b1 and the surface 11b2 in the base 11. The reflecting portion 11d can be formed, for example, by processing a portion of the base 11 and plating the processed portion, or a separately formed reflecting portion 11d may be attached to the base 11. By such a configuration, the reflecting portion 11d reflects light that has reached from the end cap 13 and has not been coupled to the core of the optical fiber 20 in the direction away from the end cap 13, in the present embodiment, as an example, in the Y direction or a direction opposite to the Y direction. Thus, it is possible to avoid a situation in which light leaking from the end cap 13 is reflected by the base 11 or others and returns to the end cap 13, and the temperature of the end cap 13 rises. Note that the reflecting portion 11d is not limited to the configuration illustrated in FIGS. 1 and 2. Instead of the reflecting portion 11d, a scattering portion having a scattering surface that scatters light may be provided.

### Optical Processing Mechanism

FIG. 5 is a cross-sectional view taken along line V-V in FIG. 1 and is a cross-sectional view of the optical processing mechanism 40. As illustrated in FIG. 5, the cover 12 has a surface 12a positioned at an end portion on the side opposite in the Z direction and a surface 12b positioned at an end portion in the Z direction. The cover 12 covers the surface 11b1. The surface 12a faces and is in contact with the surface 11b1. The surface 11b1 of the base 11 is provided with a recessed groove 11e which is recessed in the direction opposite to the Z direction and extends in the X direction. The recessed groove 11e is a so-called V-shaped groove that forms a V-shaped cross section in a cross section intersecting the X direction. The recessed groove 11e is provided between the two surfaces 11e1 and 11e2. The surface 11e1 extends, as directed toward the Y direction, in the direction opposite to the Z direction and extends in the X direction. The surface 11e2 extends, as directed toward the Y direction, in the Z direction and extends in the X direction.

The housing chamber S surrounded by the surfaces 11e1 and 11e2 of the recessed groove 11e and the surface 12a of the cover 12 extends in the X direction. The optical fiber 20 extending in the X direction is housed in the housing chamber S.

The surfaces 11e1, 11e2, and 12a suppress positional displacement of the stripped end portion 20a in the direction orthogonal to the X direction. The surfaces 11e1, 11e2, and 12a can also be referred to as positioning portions or positional displacement prevention portions.

A treatment material 15 is housed in a portion except the optical fiber 20 in the housing chamber S. The optical processing mechanism 40 has the treatment material 15. The treatment material 15 is present around the stripped end portion 20a in a state of being in contact with the stripped end portion 20a (core wire 21). The core wire 21 has a core 21a and a cladding 21b. The treatment material 15 transmits or scatters light leaked from the cladding 21b at the stripped end portion 20a. Thus, it is possible to suppress propagation of light from the cladding 21b to a covering 22. The treatment material 15 may convert light energy into heat energy.

The treatment material 15 can be made of, for example, an inorganic adhesive having a property of transmitting or scattering light. The inorganic adhesive is, for example, a silicon-based or alumina-based adhesive. In this case, the inorganic adhesive is applied in an uncured state and then cured, resulting in a ceramic-like film. The inorganic adhesive can transmit or scatter light. Note that, when the inorganic adhesive uses an organic solvent, the organic solvent is volatilized during curing. Since the inorganic adhesive has a high heat resistance, the adhesive is suitable as the treatment material 15.

The treatment material 15 may be made of a resin material having a property of transmitting or scattering light. The resin material is, for example, silicone-based, epoxy-based, or urethane acrylate-based. The resin material may contain, for example, boron nitride, talc, or aluminum nitride (AlN) as a filler. In this case, light is also scattered by the filler. Preferably, the refractive index of the filler is higher than the refractive index of the cladding 21b. Note that the resin material and the filler are not limited to those described above.

As described above, in the present embodiment, the end cap 13 (relaxing portion) is supported by the base 11 and the holder 14 in a state of being sandwiched between the base 11 (first portion) and the holder 14 (second portion). In other words, the end cap 13 is positioned between the base 11 and the holder 14, and is in contact with each of the base 11 and the holder 14.

According to such a configuration, for example, the end cap 13 can be attached to the base 11 more easily or more reliably. For example, as compared with a case where the holder 14 is not provided, it is possible to obtain an effect that the end cap 13 can be suppressed from interfering with a tool or a component during manufacturing or stray light can be suppressed from entering the end cap 13. Note that the end cap 13 may be attached to at least one of the base 11 and the holder 14 via, for example, an adhesive. However, when the adhesive is not used for fixing the end cap 13, it is possible to obtain an advantage such as a reduction in manufacturing cost or suppression of inconvenience caused by the adhesive.

In the present embodiment, the holder 14 is provided with the cutout 14a (opening), and the connecting portion between the protruding portion 13b of the end cap 13 and the tip 20a1 of the core wire 21 of the optical fiber 20 is exposed on the side opposite to the base 11 by the cutout 14a. Such a configuration allows to check a connection state between the protruding portion 13b and the tip 20a1 through the cutout 14a by visual confirmation of an operator or photographing by a camera, for example.

In the present embodiment, the holder 14 is made of an invar material. According to such a configuration, for example, even when the end cap 13 is thermally expanded, the thermal expansion of the end cap 13 is not excessively hindered by the holder 14, so that deformation or damage of the end cap 13 or the stripped end portion 20a can be suppressed.

In the present embodiment, the end cap 13 is supported by the base 11 at one or more positions and the holder 14 at one or more positions, and is supported by both of the base 11 and the holder 14 at three or more positions in total. According to such a configuration, it is possible to more reliably suppress, for example, the positional displacement of the end cap 13.

### First Modification

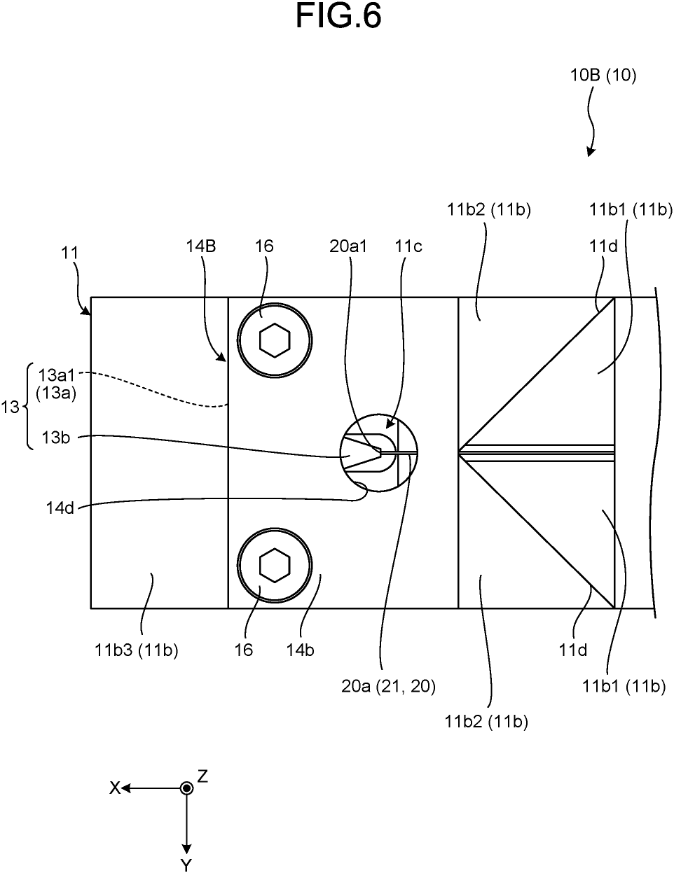

FIG. 6 is a plan view of a support 10B (10) of a first modification of the first embodiment. As illustrated in FIG. 6, in the present modification, a holder 14B is provided with a through-hole 14d as an opening instead of the cutout 14a. The support 10B has the same configuration as that of the support 10A of the first embodiment except that the holder 14B is provided with the through-hole 14d instead of the cutout 14a. The through-hole 14d penetrates the top wall 14c in the Z direction, so that a connecting portion between the protruding portion 13b of the end cap 13 and the tip 20a1 of the core wire 21 is exposed on the side opposite to the base 11. Such a configuration allows to check a connection state between the protruding portion 13b and the tip 20a1 through the through-hole 14d by visual confirmation of an operator or photographing by a camera, for example.

### Second Modification

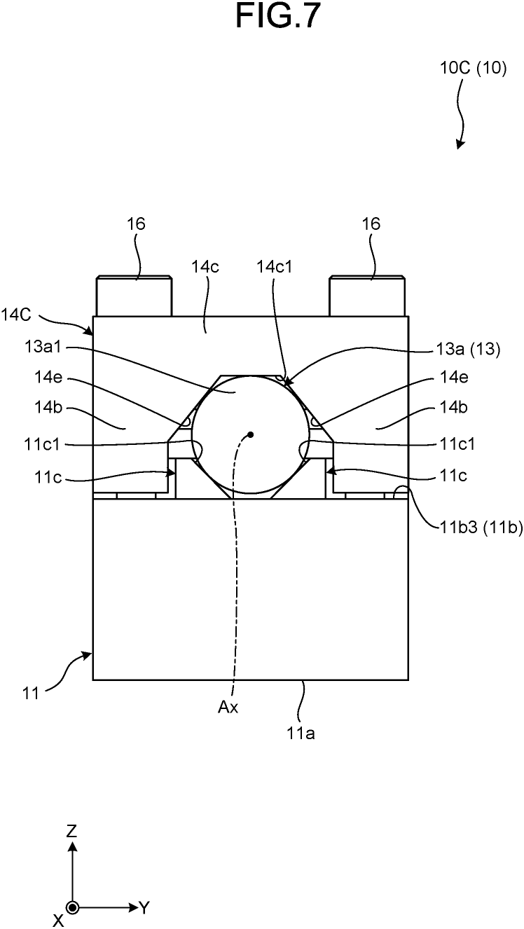

FIG. 7 is a front view of a support 10C (10) of a second modification of the first embodiment. As illustrated in FIG. 7, in the present modification, a holder 14C is provided with inclined surfaces 14e at two corners, respectively, between the two side walls 14b and the top wall 14c. The inclined surfaces 14e face inward in the radial direction of the central axis (i.e., the optical axis Ax) of the columnar portion 13a of the end cap 13. The inclined surfaces 14e are planes extending in the direction (tangential direction) orthogonal to the radial direction of the optical axis Ax and extending in the axial direction of the optical axis Ax, that is, in the Z direction. The outer peripheral surface of the columnar portion 13a is in contact with these inclined surfaces 14e. The columnar portion 13a, that is, the end cap 13, is supported by the support 10C by line contact with five surfaces in total of the two inclined surfaces 11c1 of the protrusion 11c, the two inclined surfaces 14e, and the inner surface 14c1 of the top wall 14c of the holder 14, or by surface contact with an elongated surface extending in the Z direction with a very small width. Also in the present modification, the support 10C can support the end cap 13 without using an adhesive or others.

According to the present modification, the end cap 13 is supported by the base 11 at two or more positions and the holder 14 at two or more positions, and is supported by both of the base 11 and the holder 14 at four or more positions in total. According to such a configuration, it is possible to much more reliably suppress, for example, the positional displacement of the end cap 13.

### Third Modification

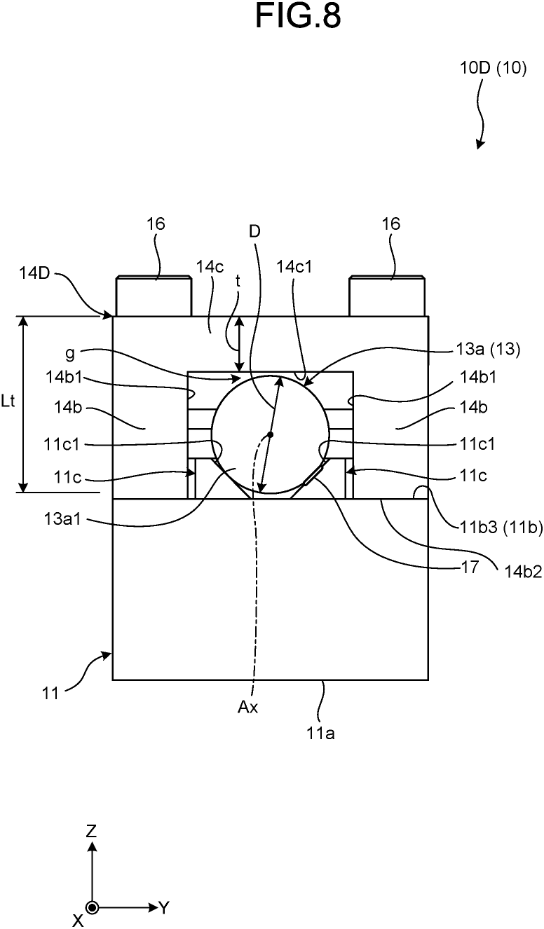

FIG. 8 is a front view of a support 10D (10) of a third modification of the first embodiment. As illustrated in FIG. 8, also in the present modification, the end cap 13 is positioned between the base 11 and a holder 14D. However, in the present modification, the end cap 13 does not contact the holder 14D, and a gap g is provided between the end cap 13 and the holder 14D. On the other hand, the end cap 13 is in contact with the base 11, and the outer peripheral surface of the end cap 13 and the inclined surface 11c1 of the protrusion 11c are coupled to each other via an adhesive 17. In other words, the end cap 13 is attached to the base 11 via the adhesive 17. According to such a configuration, the adhesive 17 can ensure that the end cap 13 is supported by the base 11 or the holder 14D, reduce force that acts on the end cap 13 from the base 11 or the holder 14D compared to a case where the gap g is not provided, and suppress deformation or damage of the end cap 13 due to the force.

In a temperature range in which the support 10D is used, for example, in a range of -20 [°C.] or higher and 120 [°C.] or lower, the support 10D is set such that the gap g is greater than 0.05 [mm], and more preferably, the gap g is greater than or equal to 0.1 [mm]. According to such a configuration, it is possible to suppress the end cap 13 from being compressed between the base 11 and the holder 14D due to thermal expansions or thermal contractions of the respective parts, and thus to suppress the end cap 13 from being deformed or damaged.

Assuming the thermal expansions of the respective parts, the size (g) of the gap g may be set so as to satisfy, for example, the following equation (1). g>ΔT(αh×t+αe×D) (1)

Where ΔT is the maximum temperature difference of the support 10D, αh is the thermal expansion coefficient of the holder 14D, t is the thickness of the top wall 14c of the holder 14D, αe is the thermal expansion coefficient of the end cap 13, and D is the diameter of the end cap 13. Note that Equation (1) is based on the assumption that the length Lt between the end surface of the holder 14D in the Z direction and the end portion of the end cap 13 in the direction opposite to the Z direction is substantially constant.

Further, from the viewpoint of suppressing the entry of a tool such as tweezers or a foreign material into the gap g, the gap g is preferably less than or equal to 0.6 [mm], and more preferably less than or equal to 0.4 [mm].

The elastic modulus of the adhesive 17 in a cured state is preferably smaller than the elastic modulus of the base 11 and the holder 14D. According to such a configuration, the protection of the end cap 13 can be further enhanced by the buffer action of the adhesive 17 which is softer than the base 11 and the holder 14D. From such a viewpoint, the adhesive 17 is preferably an organic adhesive.

Inner surfaces 14b1 and 14c1 of the holder 14D facing the end cap 13 may be provided with a layer of a light absorbing material that absorbs light by, for example, a coated black paint. According to such a configuration, it is possible to suppress stray light (leakage light) reaching the inner surfaces 14b1 and 14c1 from being reflected by the inner surfaces 14b1 and 14c1 and being coupled to the end cap 13. Note that the inner surfaces 14b1 and 14c1 can also be simply referred to as surfaces. The layer of light absorbing material may be provided on a surface of the base 11 facing the end cap 13.

Note that in the present modification, the surface 11b3 of the base 11 and a bottom surface 14b2 of the holder 14D are in contact with each other. The end cap 13 is attached to the base 11 as an example, but is not limited to this example, and the end cap 13 may be attached to the holder 14D and the gap g may be provided between the end cap 13 and the base 11.

### Fourth Modification

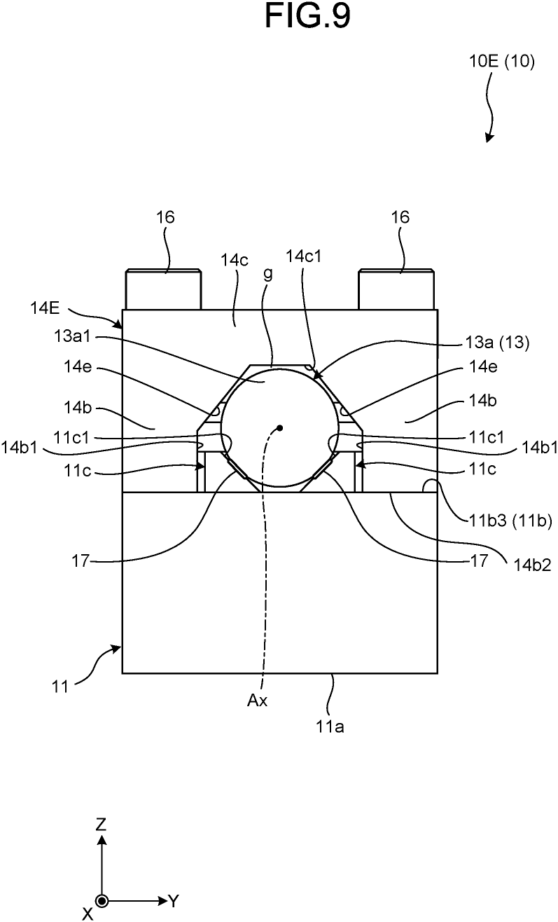

FIG. 9 is a front view of a support 10E (10) of a fourth modification of the first embodiment. As illustrated in FIG. 9, in the present modification, the gap g is provided between the end cap 13 and a holder 14E in the same configuration as that of the support 10C (see FIG. 7) of the second modification. In the present modification, the end cap 13 is attached to the two protrusions 11c of the base 11 via the adhesive 17. In other words, the end cap 13 is attached to the base 11 at a plurality of positions. Such a configuration also allows to obtain the same effect as that of the above third modification using the gap g and the adhesive 17.

Note that the end cap 13 may be attached to the holder 14E at a plurality of positions, and the gap g may be provided between the end cap 13 and the base 11.

### Fifth Modification

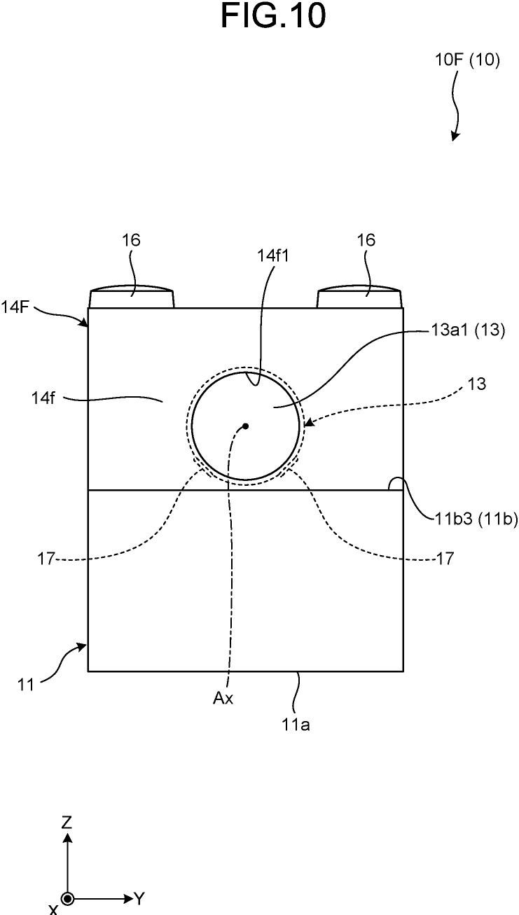

FIG. 10 is a front view of a support 10F (10) of a fifth modification of the first embodiment. As illustrated in FIG. 10, a holder 14F has an end wall 14f. The end wall 14f intersects and is orthogonal to the X direction at a predetermined thickness at a position shifted in the X direction from the end surface 13a1 in the X direction in the end cap 13, and the end wall 14f is provided with an opening 14f1 that exposes a light receiving region in the end surface 13a1. According to such a configuration, the holder 14F can cover a wider range around the end cap 13, and thus further enhance the protection of the end cap 13. The end wall 14f is an example of a second covering portion that covers a peripheral edge portion of the end surface 13a1 serving as the light receiving surface, and the peripheral edge portion of the end surface 13a1 is an example of a portion away from the light receiving region.

As illustrated in FIG. 10, the end wall 14f covers the adhesive 17 at a position shifted in the X direction with respect to the end surface 13a1, in other words, on the side opposite to the tip 20a1 (see FIG. 3 and other figures) of the optical fiber 20 with respect to the end surface 13a1. According to such a configuration, it is possible to block, by the end wall 14f, stray light (leakage light) that travels substantially along the direction opposite to the X direction toward the adhesive 17, and to suppress deterioration of the adhesive 17 due to the stray light. The end wall 14f is an example of a first covering portion.

### Sixth Modification

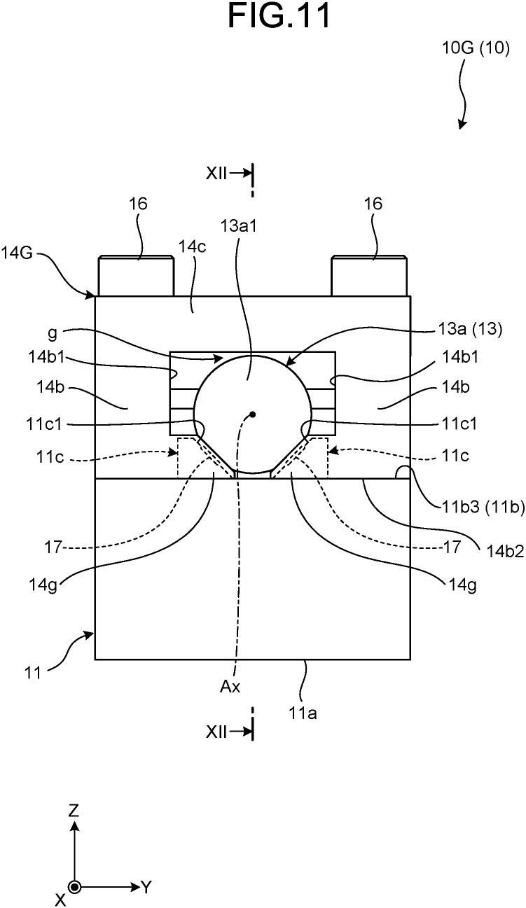

FIG. 11 is a front view of a support 10G (10) of a sixth modification of the first embodiment, and FIG. 12 is a cross-sectional view taken along line XII-XII in FIG. 11. In the present modification, as illustrated in FIG. 12, the side wall 14b and the top wall 14c of a holder 14G extend forward in the X direction from the end surface 13a1 of the end cap 13. As illustrated in FIGS. 11 and 12, the two side walls 14b each have protruding portions 14g that protrude in the direction approaching each other from a portion close to the surface 11b3 of the base 11. The protruding portions 14g partially cover the peripheral edge portion of the end cap 13 so as not to block the optical path of light passing through the end cap 13, and cover the adhesive 17 on the side opposite to the tip 20a1 of the optical fiber 20 with respect to the end surface 13a1. According to such a configuration, the top wall 14c, the side wall 14b, and the protruding portions 14g can further enhance the protection of the end cap 13. The protruding portions 14g can block stray light that travels substantially along the direction opposite to the X direction toward the adhesive 17, and can suppress deterioration of the adhesive 17 due to the stray light. The protruding portions 14g are an example of the first covering portion and are also an example of the second covering portion.

### Seventh Modification

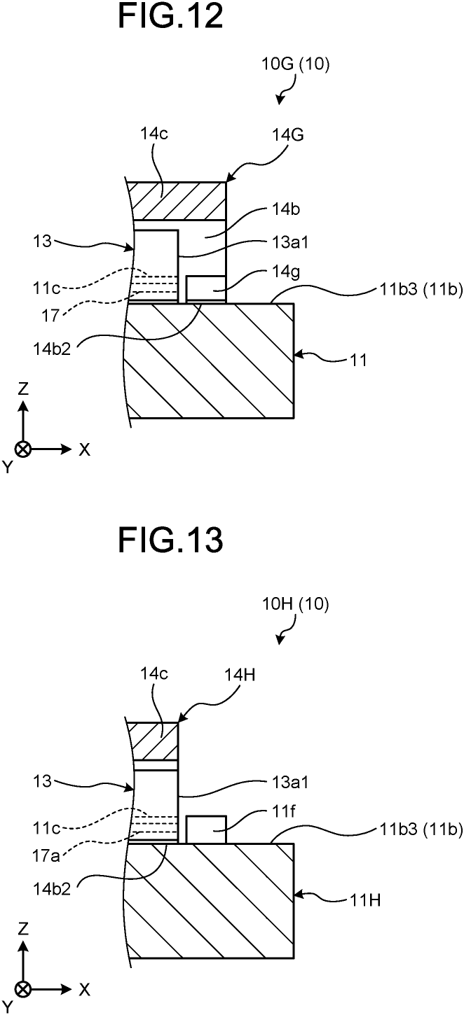

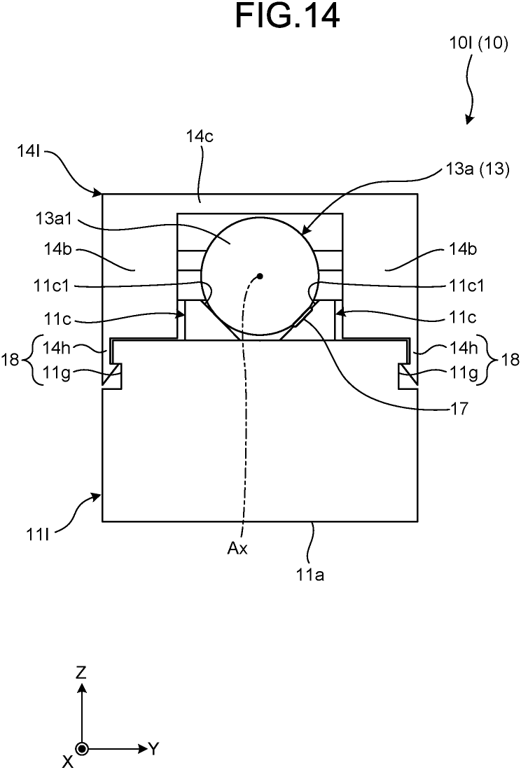

FIG. 13 is a cross-sectional view of a support 10H (10) of a seventh modification of the first embodiment at the same position as FIG. 12. In the present modification, a holder 14H is not provided with a protruding portion, and instead, a base 11H is provided with a protruding portion 11f. The protruding portion 11f has the same shape and configuration as those of the protruding portions 14g of the above sixth modification. However, the protruding portion 11f protrudes in the Z direction from the surface 11b3 of the base 11H. According to such a configuration, the protruding portion 11f can further enhance the protection of the end cap 13. The protruding portion 11f can block stray light that travels substantially along the direction opposite to the X direction toward the adhesive 17, and can suppress deterioration of the adhesive 17 due to the stray light. The protruding portion 11f is an example of the first covering portion and is also an example of the second covering portion.

### Eighth Modification

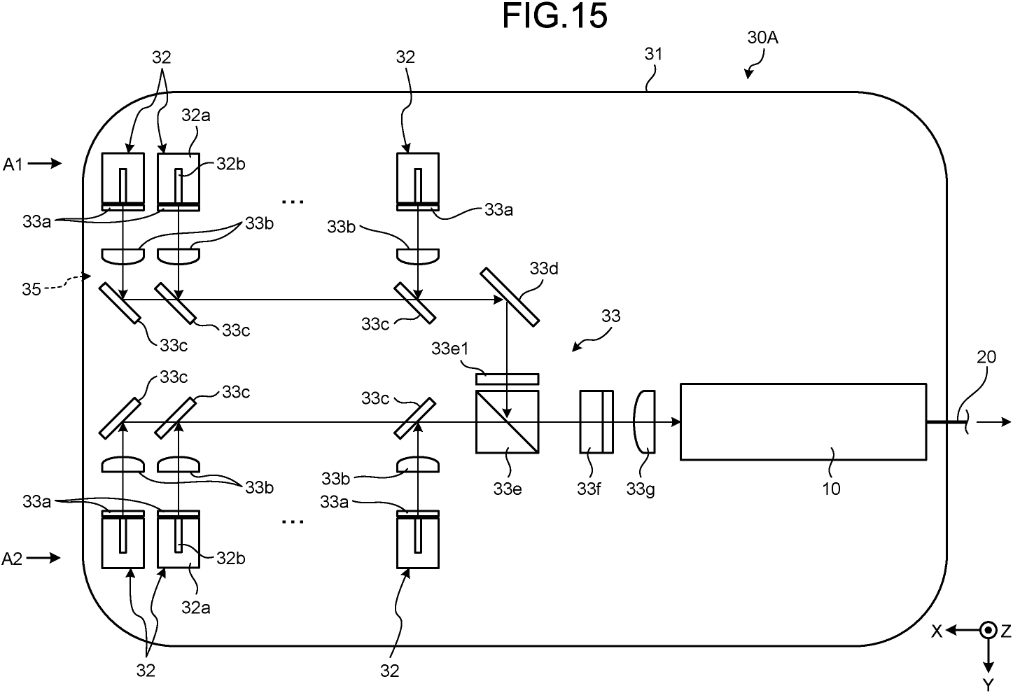

FIG. 14 is a front view of a support 101 (10) of an eighth modification of the first embodiment. As illustrated in FIG. 14, in the present modification, a base 11I and a holder 14I are connected via a snap-fit mechanism 18. The snap-fit mechanism 18 includes a recess 11g provided in the base 11I, and a hook 14h having a claw and an arm to be inserted into the recess 11g. Upon mounting the holder 14I on the base 11I, the holder 14I is brought closer to the base 11I in the direction opposite to the Z direction. The holder 14I is further moved in the direction opposite to the Z direction in a state in which the arm of the hook 14h is elastically bent and deformed by relative pressing from the base 11I. At the time when the claw of the hook 14h reaches the position overlapping with the recess 11g, the pressing on the hook 14h from the base 11I is released, whereby the claw is inserted into the recess 11g, and the mounted state illustrated in FIG. 14 in which the holder 14I is mounted on the base 11I is obtained. In the mounted state, the claw is caught by the recess 11g, so that the base 11I and the holder 14I are suppressed from being separated from each other. Note that the snap-fit mechanism 18 is not limited to the example of FIG. 14, and the recess may be provided in the holder 14I and the claw may be provided in the base 11I. The snap-fit mechanism may be configured to be capable of fixing the base 11I and the holder 14I to each other, and may be provided in a part different from the base 11I and the holder 14I.

### Second Embodiment

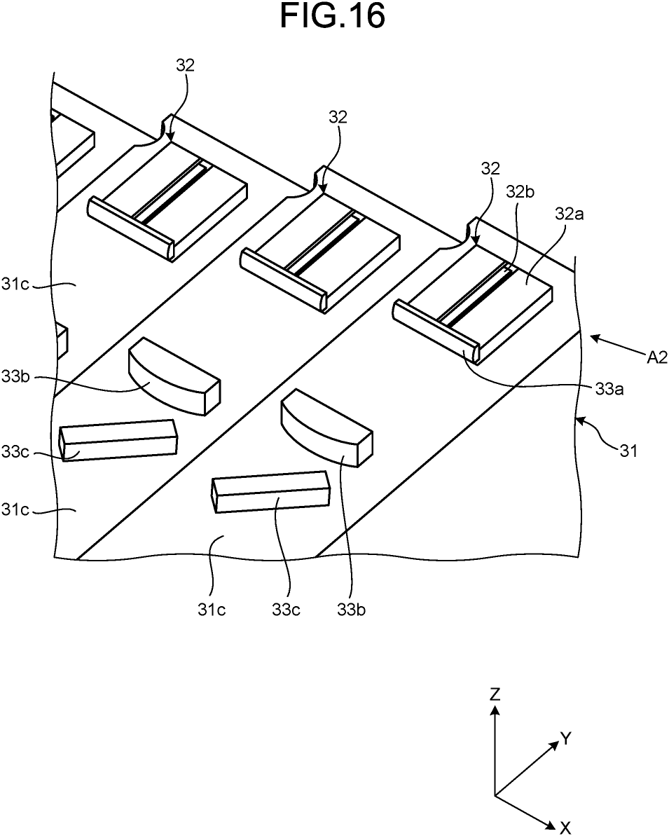

FIG. 15 is a schematic configuration diagram of a light emitting device 30A of a second embodiment, and is a plan view of the inside of the light emitting device 30A as viewed in the direction opposite to the Z direction in a state in which a cover is removed. The light emitting device 30A is an example of an optical device, and can also be referred to as a semiconductor laser module.

As illustrated in FIG. 15, the light emitting device 30A includes a base 31, an optical fiber 20 fixed to the base 31, a plurality of light emitting units 32, and a light combining unit 33 that combines light from the plurality of light emitting units 32.

The optical fiber 20 is an output optical fiber, and is fixed to the base 31 via the support 10 of the first embodiment or the modification thereof.

The support 10 may be configured integrally with the base 31 as a part of the base 31, or the support 10 configured as a separate part from the base 31 may be attached to the base 31 via a fixture such as a screw, for example.

The base 31 is made of a material having high thermal conductivity, such as a copper-based material or an aluminum-based material, for example. The base 31 is covered with a cover (not illustrated). The optical fiber 20, the light emitting unit 32, the light combining unit 33, and the support 10 are housed and sealed in a housing chamber formed between the base 31 and the cover.

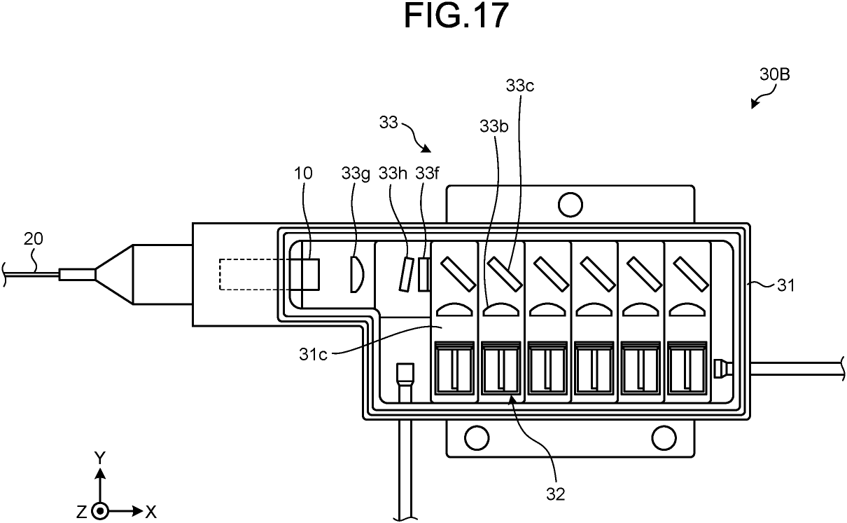

FIG. 16 is a perspective view of a portion of the light emitting device 30A. As illustrated in FIG. 16, the base 31 is provided with a stepped surface 31c so that the position of the light emitting unit 32 is shifted in the Z direction as directed toward the X direction, for each of arrays A1 and A2 (however, only the array A2 is illustrated in FIG. 16) in which the plurality of light emitting units 32 is aligned at a predetermined interval (e.g., constant interval) in the X direction. The stepped surface 31c extends in the X direction and the Y direction. The light emitting units 32 are each placed on the stepped surface 31c. The X1 direction is an example of a first direction. The stepped surface can also be referred to as a placement surface. By such a configuration, in a portion where the light emitting unit 32, a collimator lens 33b, and a mirror 33c are provided, the thickness of the base 31 in the Z direction increases as directed toward the X direction.

The light emitting unit 32 is, as an example, a chip-on sub-mount. The light emitting units 32 each include a sub-mount 32a and a light emitting element 32b mounted on the sub-mount 32a. The light emitting element 32b is, for example, a semiconductor laser chip. A plurality of the light emitting elements 32b outputs, for example, light of the same wavelength (single wavelength).

As illustrated in FIG. 15, light output from the plurality of light emitting elements 32b is combined by the light combining unit 33. The light combining unit 33 includes optical components such as collimator lenses 33a and 33b, mirrors 33c and 33d, a combiner 33e, and condenser lenses 33f and 33g. The optical components included in the light combining unit 33 are an example of an optical system that optically connects light emitting element 32b (light emitting unit 32) and optical fiber 20.

The collimator lens 33a collimates light in the Z direction (fast axis direction), and the collimator lens 33b collimates light in the X2 direction (slow axis direction). The collimator lens 33a is, for example, attached to the sub-mount 32a and integrated with the light emitting unit 32. The collimator lens 33b is placed on the stepped surface 31c on which the corresponding light emitting unit 32 is mounted.

The mirror 33c directs the light from the collimator lens 33b toward the combiner 33e. The mirror 33c is placed on the stepped surface 31c on which the corresponding light emitting unit 32 and collimator lens 33b are mounted. In other words, the light emitting unit 32, the collimator lens 33b through which light from the light emitting element 32b of the light emitting unit 32 passes, and the mirror 33c that reflects light from the collimator lens 33b are mounted on the same stepped surface 31c. In other words, in each of the arrays A1 and A2, the light emitting unit 32, the collimator lens 33b, and the mirror 33c which are aligned in the Y direction are mounted on the same stepped surface 31c. Note that the position of the stepped surface 31c in the Z direction and the size of the mirror 33c in the Z direction are set so as not to interfere with light from another mirror 33c. The light emitting unit 32, the collimator lens 33b, and the mirror 33c which are mounted on the stepped surface 31c may be simply hereinafter referred to as mounted components. The light emitting unit 32, the collimator lens 33b, and the mirror 33c may not be mounted on the same stepped surface (plane).

The combiner 33e combines the light from the two arrays A1 and A2 and outputs the combined light toward the condenser lens 33f. The light from the array A1 is input to the combiner 33e via the mirror 33d and a half-wave plate 33e1, and the light from the array A2 is directly input to the combiner 33e. The half-wave plate 33e1 rotates the polarization plane of the light from the array A1. The combiner 33e can also be referred to as a polarization combining element.

The condenser lens 33f condenses light in the Z direction (fast axis direction). The condenser lens 33g condenses the light from the condenser lens 33f in the Y direction (slow axis direction) and optically couples the light to the end portion of the optical fiber 20. Note that the condenser lens 33g may be provided on the support 10 or may be provided on the base 31. The condenser lens 33f may be provided on the support 10.

The effect of the above first embodiment is also obtained in the light emitting device 30A of the present embodiment.

### Third Embodiment

FIG. 17 is a plan view of a light emitting device 30B of a third embodiment. The light emitting device 30B is an example of an optical device, and can also be referred to as a semiconductor laser module. In the present embodiment, the stepped surface 31c extends in the X direction and the Y direction, is shifted in the Z direction, and is formed in a stepped shape. The light from the mirror 33c is coupled to the tip 20a1 (not illustrated in FIG. 17) of the core wire 21 of the optical fiber 20 supported by the support 10 via the condenser lens 33f, a low-pass filter 33h, and the condenser lens 33g. Also in the present embodiment, the thickness of the base 31 in the Z direction increases as directed toward the X direction. The effect of the above first embodiment is also obtained in the light emitting device 30B of the present embodiment.

While the embodiments of the disclosure have been exemplified above, the embodiments described above have been presented by way of example only, and are not intended to limit the scope of the inventions. The embodiments described above may be practiced in a variety of other forms, and various omissions, substitutions, combinations, and changes may be made to an extent without departing from the spirit of the inventions. The specifications (structure, type, direction, model, size, length, width, thickness, height, number, arrangement, position, material, and others) of each configuration, shape, and others may be appropriately changed.

The disclosure can be used in an optical fiber support structure and a semiconductor laser module.

According to the disclosure, it is possible to obtain an optical fiber support structure and a semiconductor laser module having an improved and novel configuration with fewer inconveniences.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical fiber support structure comprising:
a first portion configured to support an optical fiber including a core wire and a covering surrounding the core wire, the core wire including a core and a cladding;
a second portion attached to the first portion; and
a relaxing portion that is connected to an end portion of the core wire and that is positioned between the first portion and the second portion, the relaxing portion having a light receiving surface configured to receive light input from a space, an area of the light receiving surface being larger than an area of the end portion of the core wire.

2. The optical fiber support structure according to claim 1, wherein the relaxing portion is in contact with or attached to each of the first portion and the second portion.

3. The optical fiber support structure according to claim 1, wherein the relaxing portion is supported by the first portion at one or more positions and the second portion at one or more positions, and is supported by both of the first portion and the second portion at three or more positions in total.

4. The optical fiber support structure according to claim 3, wherein the relaxing portion is supported by the first portion at two or more positions and the second portion at two or more positions.

5. The optical fiber support structure according to claim 1, wherein
the relaxing portion is attached to one of the first portion and the second portion, and
a gap is provided between the relaxing portion and a remaining one of the first portion and the second portion.

6. The optical fiber support structure according to claim 5, wherein the gap is configured to be secured at -20 [°C.] or higher and 120 [°C.] or lower.

7. The optical fiber support structure according to claim 5, wherein the gap is greater than or equal to 0.05 [mm] and less than or equal to 0.6 [mm] at -20 [°C.].

8. The optical fiber support structure according to claim 1, wherein the second portion is provided with an opening through which a connecting portion between the end portion of the core wire and the relaxing portion is exposed to a side opposite to the first portion.

9. The optical fiber support structure according to claim 8, wherein the opening is a through-hole.

10. The optical fiber support structure according to claim 8, wherein the opening is a cutout.

11. The optical fiber support structure according to claim 1, wherein the second portion is made of an invar material that shrinks more than a normal temperature at a temperature higher than the normal temperature.

12. The optical fiber support structure according to claim 1, wherein the relaxing portion is a transparent material having a transmittance of 99% or more with respect to the light input to the light receiving surface.

13. The optical fiber support structure according to claim 1, wherein the relaxing portion is made of a material having a same refractive index as a refractive index of the core of the core wire.

14. The optical fiber support structure according to claim 1, wherein the relaxing portion is made of a silica-based glass material.

15. The optical fiber support structure according to claim 1, wherein the end portion of the core wire and the relaxing portion are fusion-bonded to each other.

16. The optical fiber support structure according to claim 1, wherein the relaxing portion is supported by at least one of the first portion and the second portion via an adhesive.

17. The optical fiber support structure according to claim 16, wherein an elastic modulus of the adhesive in a cured state is smaller than an elastic modulus of the at least one of the first portion and the second portion.

18. The optical fiber support structure according to claim 16, wherein the adhesive is an organic adhesive.

19. The optical fiber support structure according to claim 1, wherein
the relaxing portion is supported by at least one of the first portion and the second portion via an adhesive, and
the at least one of the first portion and the second portion includes a first covering portion configured to cover the adhesive on a side opposite to the end portion of the core wire with respect to the light receiving surface.

20. The optical fiber support structure according to claim 1, wherein at least one of the first portion and the second portion includes a second covering portion configured to cover a portion away from a light receiving region of the light receiving surface.

21. The optical fiber support structure according to claim 1, further comprising a fixture configured to fix the first portion and the second portion.

22. The optical fiber support structure according to claim 1, wherein the first portion and the second portion are coupled to each other via a snap-fit mechanism.

23. The optical fiber support structure according to claim 1, wherein
the optical fiber includes a stripped end portion in which the covering is removed in a predetermined section from the end portion of the core wire such that the core wire is exposed, and
the optical fiber support structure further comprises a treatment material that is housed in a housing chamber provided in the first portion to be present around the stripped end portion, the treatment material being configured to transmit or scatter light leaked from the stripped end portion.

24. A semiconductor laser module comprising:
the optical fiber support structure according to claim 1;
a semiconductor laser element; and
an optical system configured to guide a laser beam output from the semiconductor laser element to the relaxing portion and couple the laser beam to the end portion of the core wire via the relaxing portion.

25. The semiconductor laser module according to claim 24, comprising
a plurality of semiconductor laser elements as the semiconductor laser element, wherein
the optical system is configured to guide the laser beams output from the plurality of semiconductor laser elements to the relaxing portion and couple the laser beams to the end portion of the core wire via the relaxing portion.
